(19) United States
(12) Patent Application Publication
(10) Pub. No.: US 2021/0366942 A1
(43) Pub. Date: Nov. 25, 2021

(54) ARRAY SUBSTRATE AND MANUFACTURING METHOD THEREOF

(71) Applicant: SHENZHEN CHINA STAR OPTOELECTRONICS SEMICONDUCTOR DISPLAY TECHNOLOGY CO., LTD., Shenzhen (CN)

(72) Inventor: Xingyu ZHOU, Shenzhen (CN)

(73) Assignee: SHENZHEN CHINA STAR OPTOELECTRONICS SEMICONDUCTOR DISPLAY TECHNOLOGY CO., LTD., Shenzhen (CN)

(21) Appl. No.: 16/618,125

(22) PCT Filed: Sep. 9, 2019
(86) PCT No.: PCT/CN2019/104893

§ 371 Date: Nov. 28, 2019

(30) Foreign Application Priority Data
Aug. 12, 2019 (CN) 201910737802.3

(51) Int. Cl. H01L 27/12

(52) U.S. Cl. CPC H01L 27/1225; H01L 27/127; H01L 27/1288

(57) ABSTRACT

An array substrate and a manufacturing method thereof, the array substrate includes a glass substrate, a barrier layer, a buffer layer, an active layer, a gate insulating layer, a gate electrode layer, an interlayer insulation layer, a source/drain electrode layer, a passivation layer, and a pixel electrode which are disposed layer by layer. The manufacturing method includes providing the glass substrate, manufacturing the barrier layer, manufacturing the buffer layer, manufacturing the active layer, manufacturing the gate insulating layer, manufacturing the gate electrode layer, a patterning step, a step of doping plasma, manufacturing the interlayer insulation layer, manufacturing the source/drain electrode layer, manufacturing the passivation layer, and manufacturing the pixel electrode.

### FIELD OF INVENTION

The present disclosure relates to field of display technology, and particularly relates to an array substrate and a manufacturing method thereof of a top-gate self-alignment structure.

### BACKGROUND OF INVENTION

Flat-panel displays have many beneficial effects, such as thin bodies, power saving, no radiation, etc., and have been widely used. Current flat-panel displays primarily include liquid crystal displays (LCDs) and organic light emitting displays (OLEDs).

Presently, in active array flat-panel displays, single-gate oxide semiconductor thin film transistors (single-gate TFTs) are generally adopted on array substrates. The single-gate oxide semiconductor thin film transistors are known as array substrates of top-gate self-alignment structures, and in the manufacturing method of them, because quantity of masks required to adopt in mask processes is too much, and processes applicable for the oxide semiconductor thin film transistors are complicated, so that production efficiency is low, and cost of the processes is high.

Therefore, it is necessary to develop a new style array substrate and manufacturing method thereof to overcome the defect of prior art.

### SUMMARY OF INVENTION

The purpose of the present disclosure is to provide an array substrate and a manufacturing method thereof. Through removing a light shielding (LS) layer on a current array substrate, flatness under a semiconductor channel region of a thin film transistor can be ensured. Further, adding a light shielding layer on a polarizer corresponding to the thin film transistor, which is after the polarizer of the liquid crystal display product being attached, attaching the light shielding layer on outside of the polarizer to shield a light source of a backlight, so that protects the semiconductor channel region of the thin film transistor to prevent from influence of light, and meanwhile saves cost of masks of manufacturing the light shielding layer and shortens production cycle of the array substrate, thereby shortening production cycle of the overall process of the display panel.

In order to realize the purpose mentioned above, an embodiment of the present disclosure provides a manufacturing method of an array substrate, which includes steps as follows:

Providing a glass substrate, and cleaning the glass substrate.

Manufacturing a barrier layer, manufacturing the barrier layer on the glass substrate and performing a patterning process.

Manufacturing a buffer layer, manufacturing the buffer layer on the barrier layer.

Manufacturing an active layer, manufacturing the active layer on the buffer layer.

Manufacturing a gate insulating layer, manufacturing the gate insulating layer on the active layer.

Manufacturing a gate electrode layer, manufacturing the gate electrode layer on the gate insulating layer.

A patterning step, manufacturing a photoresist layer on the gate electrode layer, and sequentially etching the gate electrode layer, the gate insulating layer, and the active layer to obtain the gate electrode layer, the gate insulating layer, and the active layer; modifying the photoresist layer and etching again to remove an edge section of the gate electrode layer and the gate insulating layer to expose two ends of the active layer.

A step of doping plasma, removing the photoresist layer, and doping the plasma on the two ends of the active layer to form a doping region and a channel region on the active layer.

Manufacturing an interlayer insulation layer, manufacturing an interlayer insulation layer on the gate electrode layer and performing a patterning process.

Manufacturing a source/drain electrode layer, manufacturing the source/drain electrode layer on the interlayer insulation layer, and performing a patterning process.

Manufacturing a passivation layer, manufacturing the passivation layer on the source/drain electrode layer.

Manufacturing a pixel electrode, manufacturing the pixel electrode on the passivation layer.

Further, the patterning step specifically includes:

A step of manufacturing the photoresist layer, coating a layer of photoresist material on the gate electrode layer, and using a halftone mask plate on the layer of photoresist material to perform a photo (ultraviolet light) lithography process to expose and develop to form the photoresist layer; wherein a cross section of the photoresist layer is a convex shape.

A first patterning step, sequentially etching the gate electrode layer, the gate insulating layer, and the active layer to obtain the gate electrode layer, the gate insulating layer, and the active layer;

A step of amending the photoresist layer, performing a photolithography process to expose and develop to etch to remove an edge section of the convex cross section of the photoresist layer, and reserving an upper convex section of middle of the convex cross section of the photoresist layer.

A second patterning step, etching again to remove the edge section of the gate electrode layer and the gate insulating layer to expose the two ends of the active layer, wherein a portion of the buffer layer disposed corresponding to the active layer is reserved after the plurality of the etching processes.

Further, after the step of manufacturing the passivation layer and before the step of manufacturing the pixel electrode, further includes: manufacturing a planarization layer, manufacturing the planarization layer on the passivation layer.

Further, material of the barrier layer, the gate electrode layer, or the source/drain electrode layer comprises one of Mo, Al, Cu, Ti, and an alloy thereof.

Further, the buffer layer, the gate insulating layer, the interlayer insulation layer, or the passivation layer includes a SiOx layer, a SiNx layer, or a stacked structure of the SiOx layer and the SiNx layer.

Further, material of the active layer includes IGZO, IZTO, or IGZTO.

Another embodiment of the present disclosure provides an array substrate manufactured by the manufacturing method mentioned above. The array substrate includes a glass substrate, a barrier layer, a buffer layer, an active layer, a gate insulating layer, a gate electrode layer, an interlayer insulation layer, a source/drain electrode layer, a passivation layer, and a pixel electrode which are sequentially disposed layer by layer.

Further, the array substrate further includes a planarization layer, and the planarization layer is located between the passivation layer and the pixel electrode.

Further, the active layer includes a channel region, and a doping region located on two sides of the channel region; the source/drain electrode layer includes a source electrode and a drain electrode disposed opposite the doping region.

Further, a first via, a second via, and a third via are disposed on the interlayer insulation layer; a bottom of the first via is the light shielding layer, and bottoms of the second via and the third via are the doping region of the active layer; an end of the source electrode is electrically connected to the barrier layer through the first via; another end of the source electrode is electrically connected to the doping region of the active layer through the second via; the drain electrode is electrically connected to the doping region of the active layer through the third via.

The beneficial effect of an array substrate and manufacturing method thereof of the present disclosure is accomplished by sharing a halftone mask during fabrication of an active layer and fabrication of a gate layer, thereby reducing quantity of used masks, improving production efficiency, and reducing process cost.

### DETAILED DESCRIPTION OF PREFERRED EMBODIMENTS

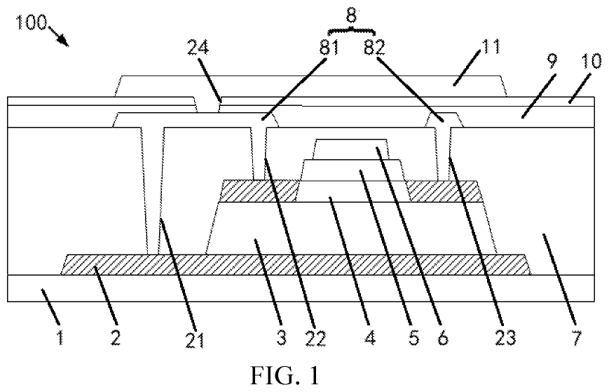

FIG. 1 is a structural schematic diagram of an array substrate of an embodiment of the present disclosure.

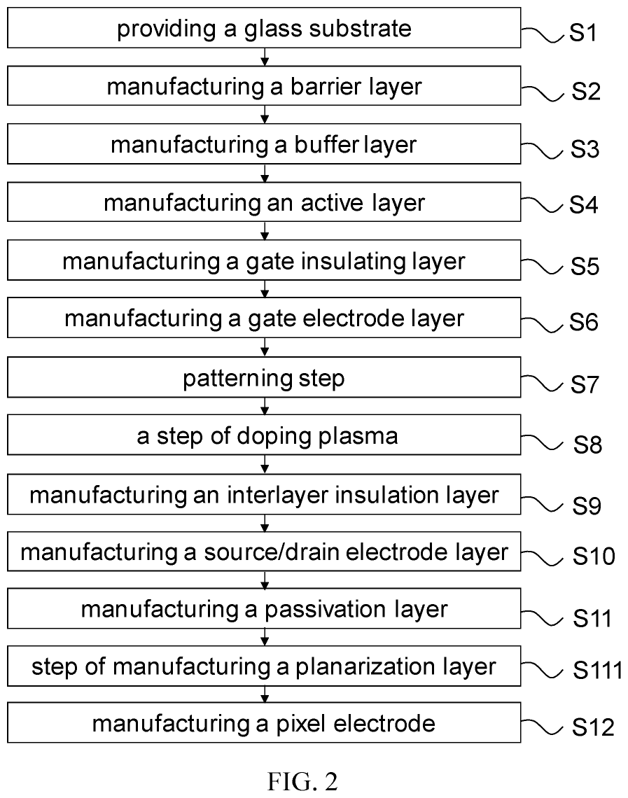

FIG. 2 is a flowchart of a manufacturing method of the array substrate of an embodiment of the present disclosure.

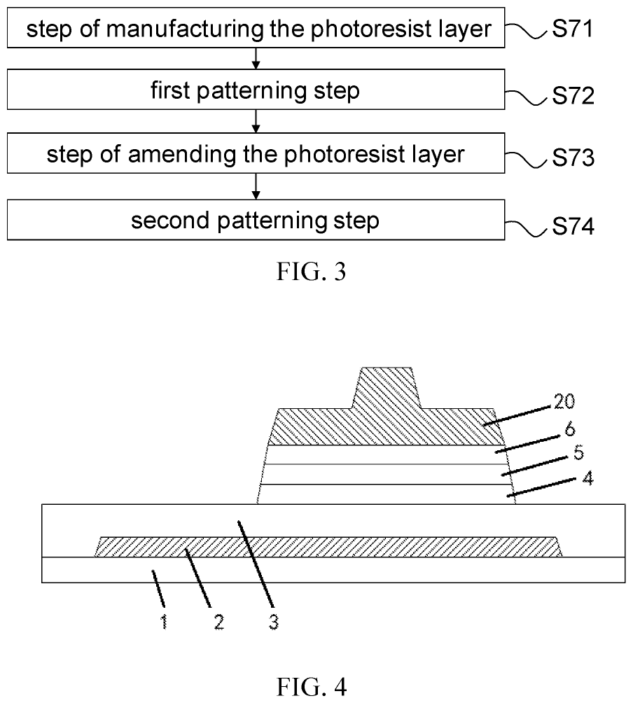

FIG. 3 is a flowchart of the patterning step in FIG. 2.

FIG. 4 is a structural schematic diagram of a semi-manufactured product after finishing the step of manufacturing the source/drain electrode layer.

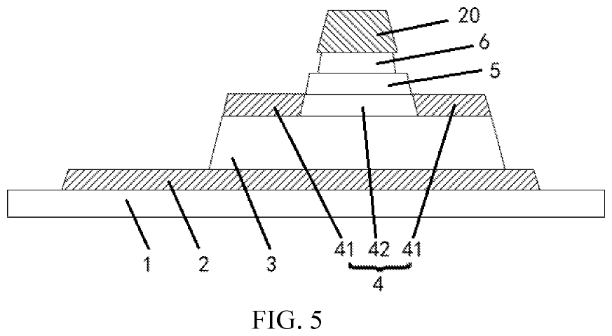

FIG. 5 is a structural schematic diagram of the semi-manufactured product after finishing the step of manufacturing the source/drain electrode layer.

### DETAILED DESCRIPTION OF PREFERRED EMBODIMENTS

The technical solutions in the embodiments of the present disclosure are clearly and completely described in the following with reference to the accompanying drawings in the embodiments of the present disclosure. Obviously, the described embodiments are only part of the embodiments of the present disclosure, but are not all embodiments of the present disclosure. All other embodiments obtained by those skilled in the art based on the embodiments of the present disclosure without creative efforts are within the scope of the present disclosure.

The terms “first”, “second”, “third” and the like (if there are any) in the specification, claims, and the accompanying drawings mentioned above of the present disclosure are used to distinguish similar objects, and are not necessarily used to describe a particular order or a sequential order. It should be understood, that the objects described are interchangeable under an appropriate situation. Moreover, the terms “comprising” and “having” and any deformation of them are intended to cover non-exclusive inclusions.

In addition, in the specification, the word “comprising” is to be understood to include the component, but does not exclude any other component. Further, in the specification, “on” means located above or below the target component, and does not mean that it must be on the top based on the direction of gravity.

Steps of all methods described herein can be performed in any suitable order unless this article has clear opposite dictations. The changes of the present disclosure are not limited to sequence of steps described. The use of any and all implementations or exemplary language (e.g., “such as” or “for example”) provided herein, is intended merely to better illuminate the present disclosure and does not pose a limitation on the scope of the present disclosure unless otherwise claimed. Numerous modifications and adaptations will be readily apparent to persons skilled in the art without departing from the spirit and scope of the present disclosure.

Please refer to FIG. 1, an embodiment of the present disclosure provides an array substrate 100, including a glass substrate 1, a barrier layer 2, a buffer layer 3, an active layer 4, a gate insulating layer 5, a gate electrode layer 6, an interlayer insulation layer 7, a source drain/electrode layer 8, a passivation layer 9, and a pixel electrode 11 which are sequentially disposed layer by layer.

In this embodiment, the array substrate 100 further includes a planarization layer 10, and the planarization layer 10 is located between the passivation layer 9 and the pixel electrode 11. The purpose of disposing the planarization layer 10 is for making the pixel electrode 11 to be more flat.

In this embodiment, the active layer 4 includes a channel region 42, and a doping region 41 located on two sides of the channel region 42. The source/drain electrode layer 8 includes a source electrode 81 and a drain electrode 82 disposed opposite the doping region 41.

An end of the source electrode 81 is electrically connected to the barrier layer 2 through the first via 21. Another end of the source electrode 81 is electrically connected to the doping region 41 of the active layer 4 through the second via 22. Portions of the source/drain electrode layers 8 filled the first via 21 and the second via 22 are connected to each other to constitute the source electrode 81. A portion of the source/drain electrode layer 8 filled the third via constitutes the drain electrode 82. Projections on the glass substrate 1 of the source electrode 81, the drain electrode 82 and the gate electrode layer 6 do not overlap with each other.

Material of the barrier layer 2, the gate electrode layer 6, or the source/drain electrode layer 8 includes one of Mo, Al, Cu, Ti, and an alloy thereof. The barrier layer 2 is used for shielding light or blocking a heat source.

The buffer layer 3, the gate insulating layer 5, the interlayer insulation layer 7, or the passivation layer 9 includes a SiOx layer, a SiNx layer, or a stacked structure of the SiOx layer and the SiNx layer.

Material of the active layer 4 includes IGZO, IZTO, or IGZTO. A thickness of the active layer 4 ranges from 100 Å to 1000 Å.

A thickness of the barrier layer 2 ranges from 500 Å to 10000 Å.

A thickness of the buffer layer 3 and the passivation layer 9 ranges from 1000 Å to 5000 Å.

A thickness of the gate insulating layer 5 ranges from 1000 Å to 3000 Å.

A thickness of the gate electrode layer 6, the source/drain electrode layer 8 and the interlayer insulation layer 7 ranges from 2000 Å to 10000 Å.

Please refer to FIG. 2, an embodiment of the present disclosure provides a manufacturing method of the array substrate 100, which includes steps S1 to S12.

S1: providing a glass substrate 1, and cleaning the glass substrate 1.

S2: manufacturing a barrier layer 2, depositing a layer of metal with a thickness ranging from 500 Å to 10000 Å on the glass substrate 1 to manufacture the barrier layer 2 and to perform a patterning process. The metal includes one of Mo, Al, Cu, Ti, and an alloy thereof. The barrier layer 2 is used for shielding light or blocking a heat source.

S3: manufacturing a buffer layer 3, depositing a SiOx layer, a SiNx layer, or a stacked structure of the SiOx layer and the SiNx layer on the barrier layer 2 to manufacture the buffer layer 3. A thickness of the buffer layer 3 ranges from 1000 Å to 5000 Å.

S4: manufacturing an active layer 4, depositing oxide material with a thickness ranging from 100 Å to 1000 Å on the buffer layer 3 to manufacture the active layer 4. The oxide material includes IGZO, IZTO, or IGZTO.

S5: manufacturing a gate insulating layer 5, depositing a SiOx layer, a SiNx layer, or a stacked structure of the SiOx layer and the SiNx layer on the active layer 4 to manufacture the gate insulating layer 5. A thickness of the gate insulating layer 5 ranges from 1000 Å to 3000 Å.

S6: manufacturing a gate electrode layer 6, depositing a layer of metal with a thickness ranging from 2000 Å to 10000 Å on the gate insulating layer 5 to manufacture the gate electrode layer 6. The metal includes one of Mo, Al, Cu, Ti, and an alloy thereof.

S7: a patterning step, manufacturing a photoresist layer 20 on the gate electrode layer 6, and sequentially etching the gate electrode layer 6, the gate insulating layer 5, and the active layer 4 to obtain the gate electrode layer 20, the gate insulating layer 5, and the active layer 4 which have widths equivalent to a width of the photoresist layer 20, and modifying the photoresist layer 20 and etching again to remove an edge section of the gate electrode layer 6 and the gate insulating layer 5 to expose two ends of the active layer 4. The procedure of performing the patterning process please refer to FIG. 3, FIG. 4, and FIG. 5.

S8: a step of doping plasma, removing the photoresist layer 20, and doping the plasma on the two ends of the active layer 4 to form a doping region 41 and a channel region 42 on the active layer 4. The active layer 4 which is doped by plasma forms the doping region 41, and a resistance value of it becomes small. The active layer 4 located under the gate insulating layer 5 is not doped by plasma, and it keeps characteristics of a semiconductor and acts as the channel region 42 of the array substrate 100.

S9: manufacturing an interlayer insulation layer 7, depositing a SiOx layer, a SiNx layer, or a stacked structure of the SiOx layer and the SiNx layer on the gate electrode layer 6 to manufacture the interlayer insulation layer 7. A thickness of the interlayer insulation layer 7 ranges from 2000 Å to 10000 Å, and the interlayer insulation layer 7 fully covers the patterned structure. Further, performing a patterning process to manufacture a first via 21, a second via 22, and a third via 33. A bottom of the first via 21 is the light shielding layer 2, and bottoms of the second via 22 and the third via 23 are the active layer 4. The first via 21, the second via 22 and the third via 23 are formed by performing an etching process, and a halftone mask is not necessary to be used in the process. Comparing to a tradition process which requires to use two halftone masks, it reduces a number of the used halftone masks, thereby improving production efficiency, and reducing cost of the process.

S10: manufacturing a source/drain electrode layer 8, depositing a layer of metal with a thickness ranging from 2000 Å to 10000 Å on the interlayer insulation layer 7 to manufacture the source/drain electrode layer 8, and performing a patterning process. The metal includes one of Mo, Al, Cu, Ti, and an alloy thereof. The source/drain electrode layer 8 fills the first via 21, the second via 22, and the third via 23. The source/drain electrode layer 8 forms a source electrode 81 and a drain electrode 82 disposed opposite on the doping region 41. Specifically, portions of the source/drain electrode layers 8 filled the first via 21 and the second via 22 are electrically connected to each other to constitute the source electrode 81. A portion of the source/drain electrode layer 8 filled the third via constitutes the drain electrode 82. Projections on the glass substrate 1 of the source electrode 81, the drain electrode 82 and the gate electrode layer 6 do not overlap each other.

S11: manufacturing a passivation layer 9, depositing a SiOx layer, a SiNx layer, or a stacked structure of the SiOx layer and the SiNx layer on the source/drain electrode layer 8 to manufacture the passivation layer 9. A thickness of the passivation layer 9 ranges from 1000 Å to 5000 Å.

S12: manufacturing a pixel electrode 11, depositing an indium tin oxide layer on the passivation layer 9 to manufacture the pixel electrode 11.

In this embodiment, through designing a cross section of the photoresist layer 20 in a convex shape during manufacturing the active layer 4 and manufacturing the gate layer 6, which can change a width of the photoresist layer 20 by a method of modifying the photoresist layer 20, thereby can share a halftone mask to finish two mask processes, thereby reducing the number of used masks, improving production efficiency, and reducing process cost.

In this embodiment, the patterning step S7 specifically includes:

S71: a step of manufacturing the photoresist layer 20, coating a layer of photoresist material on the gate electrode layer 6, and using a halftone mask plate on the layer of photoresist material to perform a photolithography process to expose and develop to form the photoresist layer 20. A cross section of the photoresist layer 20 is a convex shape.

S72: a first patterning step, sequentially etching the gate electrode layer 6, the gate insulating layer 5, and the active layer 4 to obtain the gate electrode layer 6, the gate insulating layer 5, and the active layer 4, which have widths equivalent to a width of the photoresist layer 20.

S73: a step of amending the photoresist layer 20, performing a photolithography process to expose and develop to etch to remove an edge section of the convex cross section of the photoresist layer 20, and reserving an upper convex section of middle of the convex cross section of the photoresist layer 20. Because the cross section of the photoresist layer 20 is a convex shape, etching speeds on a vertical direction are same, therefore, the upper convex section of the convex shape of the cross section of the amended photoresist layer 20 is reserved.

S74: a second patterning step, etching again to remove the edge section (not the channel region 42) of the gate electrode layer 6 and the gate insulating layer 5 to expose the two ends of the active layer 4. A portion of the buffer layer 3 disposed corresponding to the active layer 4 is reserved after the plurality of the etching processes. The buffer layer 3 not covered by the active layer 4 is completely etched away.

FIG. 4 is a structural schematic diagram of the semi-manufactured product after finished the first patterning step. FIG. 5 is the structural schematic diagram of a semi-manufactured product after finished the second patterning step.

In this embodiment, after the step of manufacturing the passivation layer 11 and before the step of manufacturing the pixel electrode 9, further includes:

S111: a step of manufacturing a planarization layer 10, depositing a photoresist material layer with a thickness ranging from 0.5 um to 2 um on the passivation layer 9 to manufacture the planarization layer 10, and manufacturing a fourth via 24 by a photolithography process. The pixel electrode 11 fills the fourth via 24. The purpose of manufacturing the planarization layer 10 is for making the pixel electrode 11 more flat.

It is worth mentioning that the etch processes mentioned in the present disclosure include two methods of wet etching processes and dry etching processes.

The beneficial effect of an array substrate and manufacturing method thereof of the present disclosure is through designing a cross section of the photoresist layer 20 in a convex shape during manufacturing the active layer 4 and manufacturing the gate layer 6, which can change a width of the photoresist layer 20 by a method of modifying the photoresist layer 20, thereby can share a halftone mask to finish two mask processes, thereby reducing the number of used masks, improving production efficiency, and reducing process cost.

Which mentioned above is preferred embodiments of the present disclosure, it should be noted that to those skilled in the art without departing from the technical theory of the present disclosure, can further make many changes and modifications, and the changes and the modifications should be considered as the scope of protection of the present disclosure.

1. A manufacturing method of an array substrate, comprising steps as follows:
providing a glass substrate;
manufacturing a barrier layer on the glass substrate and performing a patterning process;
manufacturing a buffer layer on the barrier layer;
manufacturing an active layer on the buffer layer;
manufacturing a gate insulating layer on the active layer;
manufacturing a gate electrode layer on the gate insulating layer;
manufacturing a photoresist layer on the gate electrode layer, and sequentially etching the gate electrode layer, the gate insulating layer, and the active layer to obtain the gate electrode layer, the gate insulating layer, and the active layer; modifying the photoresist layer and etching again to remove an edge section of the gate electrode layer and the gate insulating layer to expose two ends of the active layer;
removing the photoresist layer, and doping plasma on the two ends of the active layer to form a doping region and a channel region on the active layer;
manufacturing an interlayer insulation layer on the gate electrode layer, and performing a patterning process;
manufacturing a source/drain electrode layer, and performing a patterning process;
manufacturing a passivation layer on the source/drain electrode layer; and
manufacturing a pixel electrode on the passivation layer.

2. The manufacturing method of the array substrate as claimed in claim 1, wherein the patterning step specifically comprises:
coating a layer of photoresist material on the gate electrode layer, and using a halftone mask plate on the layer of photoresist material to perform a photolithography process to expose and develop to form the photoresist layer; wherein a cross section of the photoresist layer is a convex shape;
sequentially etching the gate electrode layer, the gate insulating layer, and the active layer to obtain the gate electrode layer, the gate insulating layer, and the active layer;
performing a photolithography process to expose and develop to etch to remove an edge section of the convex cross section of the photoresist layer, and reserving an upper convex section of middle of the convex cross section of the photoresist layer; and
etching again to remove the edge section of the gate electrode layer and the gate insulating layer to expose the two ends of the active layer, wherein a portion of the buffer layer disposed corresponding to the active layer is reserved after the plurality of the etching processes.

3. The manufacturing method of the array substrate as claimed in claim 1, wherein after manufacturing the passivation layer and before manufacturing the pixel electrode, further comprises:
manufacturing a planarization layer on the passivation layer.

4. The manufacturing method of the array substrate as claimed in claim 1, wherein material of the barrier layer, the gate electrode layer, or the source/drain electrode layer comprises one of Mo, Al, Cu, Ti, and an alloy thereof.

5. The manufacturing method of the array substrate as claimed in claim 1, wherein the buffer layer, the gate insulating layer, the interlayer insulation layer, or the passivation layer comprises a SiOx layer, a SiNx layer, or a stacked structure of the SiOx layer and the SiNx layer.

6. The manufacturing method of the array substrate as claimed in claim 1, wherein material of the active layer comprises IGZO, IZTO, or IGZTO.

7. An array substrate manufactured by the manufacturing method as claimed in claim 1, comprising a glass substrate, a barrier layer, a buffer layer, an active layer, a gate insulating layer, a gate electrode layer, an interlayer insulation layer, a source/drain electrode layer, a passivation layer, and a pixel electrode which are sequentially disposed layer by layer.

8. The array substrate as claimed in claim 7, wherein the array substrate further comprises a planarization layer, and the planarization layer is located between the passivation layer and the pixel electrode.

9. The array substrate as claimed in claim 7, wherein
the active layer comprises a channel region, and a doping region located on two sides of the channel region;
the source/drain electrode layer comprises a source electrode and a drain electrode disposed opposite the doping region.

10. The array substrate as claimed in claim 9, wherein
a first via, a second via, and a third via are disposed on the interlayer insulation layer; a bottom of the first via is the light shielding layer, and bottoms of the second via and the third via are the doping region of the active layer;
an end of the source electrode is electrically connected to the barrier layer through the first via;
another end of the source electrode is electrically connected to the doping region of the active layer through the second via;
the drain electrode is electrically connected to the doping region of the active layer through the third via.
